(19) United States
(12) Patent Application Publication
(10) Pub. No.: US 2024/0399429 A1
(43) Pub. Date: Dec. 5, 2024

(54) SUBSTRATE PROCESSING APPARATUS AND SUBSTRATE PROCESSING METHOD

(71) Applicant: SEMES CO., LTD., Cheonan-si (KR)

(72) Inventors: Ju Ha WOO, Anseong-si (KR); Young Joon HAN, Cheonan-si (KR); Sang Hu HAN, Cheonan-si (KR)

(73) Assignee: SEMES CO., LTD., Cheonan-si (KR)

(21) Appl. No.: 18/442,486

(22) Filed: Feb. 15, 2024

(30) Foreign Application Priority Data
Jun. 1, 2023 (KR) 10-2023-0070780

(51) Int. Cl. B08B 15/02; B08B 3/08

(52) U.S. Cl. CPC B08B 15/02; B08B 3/08

(57) ABSTRACT

Provided is a substrate processing apparatus and a substrate processing method that are capable of increasing exhaust volume without increasing exhaust facilities. An apparatus for processing a substrate includes: a processing chamber having a processing space for processing a substrate; a support unit for supporting the substrate in the processing space; a liquid supply unit for supplying a liquid to a substrate supported by the support unit; and an exhaust unit for exhausting the processing space, in which the exhaust unit includes: an exhaust pipe connected to the processing space; and an exhaust amplifier installed in the exhaust pipe and for supplying acceleration gas to a passage of the exhaust pipe to amplify an exhaust flow rate of exhaust gas flowing in the exhaust pipe.

### CROSS-REFERENCE TO RELATED APPLICATIONS

This application claims priority to and the benefit of Korean Patent Application No. 10-2023-0070780 filed in the Korean Intellectual Property Office on Jun. 1, 2023 the entire contents of which are incorporated herein by reference.

### TECHNICAL FIELD

The present invention relates to a substrate processing apparatus and a substrate processing method, and particularly, to a substrate processing apparatus and a substrate processing method for processing a substrate.

### BACKGROUND ART

To manufacture semiconductor devices, various processes, such as photography, deposition, ashing, etching, and ion implantation, are performed. In addition, before and after these processes are performed, a cleaning process of cleaning particles remaining on the substrate is performed.

The cleaning process is performed using various types of cleaning solutions, some of which are acidic or alkaline, and the use of acidic or alkaline cleaning solutions generates large amounts of fumes.

As a result, the cleaning process discharges exhaust gases, including fumes and by-products, to the outside during the process of cleaning the substrate.

Typically, multiple cleaning machines are coupled to a single exhaust facility, and sometimes the suction power of exhaust equipment is insufficient to handle the full exhaust volume, resulting in a lack of smooth exhaust, causing fumes and debris to impact the substrate.

Therefore, each cleaning equipment is equipped with a fan rotated by a power source in the exhaust pipe to increase the exhaust volume without increasing the exhaust facility. However, this method of increasing the exhaust volume by using the fan and the power source requires additional space for the fan and the power source to be installed, and since the fan and the power source are inserted inside the pipe, it is difficult to inspect and replace the fan and the power source during maintenance.

In addition, since each cleaning equipment often uses acid or alkaline treatment liquids, the fan and the power source with strong chemical resistance are required, and even if the fan and the power source are chemically resistant, the fan and the power source have limited lifespans and need to be replaced frequently.

### SUMMARY OF THE INVENTION

The present invention to solve the foregoing problems provides a substrate processing apparatus and a substrate processing method that are capable of increasing exhaust volume without increasing exhaust facilities.

Further, the present invention to solve the foregoing problems provides a substrate processing apparatus and a substrate processing method that are capable of increasing exhaust volume without utilizing exhaust components, such as a fan, that require a power source, or that require replacement.

The object of the present invention is not limited thereto, and other objects not mentioned will be clearly understood by those of ordinary skill in the art from the following description.

An exemplary embodiment of the present invention an apparatus for processing a substrate including: a processing chamber having a processing space for processing a substrate; a support unit for supporting the substrate in the processing space; a liquid supply unit for supplying a liquid to a substrate supported by the support unit; and an exhaust unit for exhausting the processing space, in which the exhaust unit includes: an exhaust pipe connected to the processing space; and an exhaust amplifier installed in the exhaust pipe and for supplying acceleration gas to a passage of the exhaust pipe to amplify an exhaust flow rate of exhaust gas flowing in the exhaust pipe.

According to the exemplary embodiment, the exhaust amplifier may include: an acceleration gas-side housing having an inlet passage through which the acceleration gas is introduced and a buffer-side outlet passage through which the acceleration gas is discharged; and a gas supply line connected to the inlet passage to supply the acceleration gas to the inlet passage, and the acceleration gas-side housing discharges the acceleration gas discharged from the buffer-side outlet passage into a passage of the exhaust pipe.

According to the exemplary embodiment, the acceleration gas-side housing may be disposed so that a direction of discharging the acceleration gas from the inlet passage and a direction of discharging the acceleration gas from the buffer-side outlet passage are not identical to each other.

According to the exemplary embodiment, the acceleration gas-side housing has a buffer space which communicates with the inlet passage and the buffer-side outlet passage and is formed in an area larger than the inlet passage and the buffer-side outlet passage.

According to the exemplary embodiment, the buffer space may be provided in a ring shape.

According to the exemplary embodiment, the buffer-side outlet passage may be provided in a ring shape.

According to the exemplary embodiment, the acceleration gas discharged from the buffer-side outlet passage may be provided to be discharged in a downstream direction in which the exhaust gas flows.

According to the exemplary embodiment, the acceleration gas discharged from the buffer-side outlet passage may be discharged along a face forming the passage of the exhaust pipe.

According to the exemplary embodiment, the exhaust amplifier may have a curved surface in which a face on which the acceleration gas flows is formed to be curved.

According to the exemplary embodiment, the acceleration gas discharged from the buffer-side outlet passage may be discharged to the curved surface.

According to the exemplary embodiment, an inner diameter of the curved surface may be provided to decrease and then increase in a downstream direction in which the exhaust gas flows.

According to the exemplary embodiment, the exhaust pipe may include a first exhaust pipe connected to the treating chamber, and a second exhaust pipe, and the acceleration gas-side housing may include: a first body connected with the first exhaust pipe; and a second body connected with the second exhaust pipe, and the second body and the first body may be coupled to each other, and a buffer space may be provided between the first body and the second body.

According to the exemplary embodiment, the second body may be provided so that an area of the passage increases in a direction toward the second exhaust pipe.

According to the exemplary embodiment, the first body may include: an insertion region coupled with the first exhaust pipe; and a protruding region extending from the insertion region in a direction in which the exhaust gas flows, and the protruding region may be provided so that an inner diameter of the passage decreases in the direction in which the exhaust gas flows.

According to the exemplary embodiment, the first body may further include an extended region extended from the protruding region in a direction in which the exhaust gas flows, and the second body may be engaged with an inner diameter or an outer diameter of the extended region, and the buffer space may be provided between the first body and the second body.

According to the exemplary embodiment, the apparatus may further include a damper installed in the exhaust pipe and for adjusting an area of exhaust on a passage through which the exhaust flows.

Another exemplary embodiment of the present invention provides a method of processing a substrate, the method including: supplying a treatment liquid to a substrate loaded into a processing space and exhausting the processing space through an exhaust pipe connected to the processing space to liquid-treat a substrate, in which acceleration gas is supplied to the exhaust pipe from the outside, and an exhaust flow rate of exhaust gas in the processing space is amplified by a flow speed of the acceleration gas.

According to the exemplary embodiment, atmosphere in the processing space may be exhausted through a passage of the exhaust pipe, the exhaust pipe may be formed with an inlet passage through which the acceleration gas is supplied into the passage of the exhaust pipe, and the inlet passage may be formed with a ring-shaped buffer space surrounding an inside of the passage of the exhaust pipe, and the acceleration gas may be supplied to the passage of the exhaust pipe through the buffer space.

According to the exemplary embodiment, the acceleration gas may be provided to flow along an inner surface of the exhaust pipe toward a direction in which the exhaust gas flows.

Still another exemplary embodiment of the present invention provides an apparatus for processing a substrate, the apparatus including: a processing chamber having a processing space for processing a substrate; a support unit for supporting the substrate in the processing space; a liquid supply unit for supplying a liquid to a substrate supported by the support unit; and an exhaust unit for exhausting the processing space, in which the exhaust unit includes: an exhaust pipe connected to the processing space and exhausting the processing space; and an exhaust amplifier installed in the exhaust pipe and amplifying an exhaust pressure; and the exhaust amplifier includes: an acceleration gas-side housing having an inlet passage through which the acceleration gas is introduced and a buffer-side outlet passage through which the acceleration gas is discharged, and a buffer space which communicates with the inlet passage and the buffer-side outlet passage, is formed in an area larger than the inlet passage and the buffer-side outlet passage, and is provided in a ring shape; and a gas supply line connected to the inlet passage and for supplying the acceleration gas to the inlet passage, and the acceleration gas-side housing is disposed so that a direction of discharging the acceleration gas from the inlet passage and a direction of discharging the acceleration gas from the buffer-side outlet passage are not identical to each other, and the acceleration gas discharged from the buffer-side outlet passage is discharged along a face forming a passage of the exhaust pipe.

According to the present invention, it is possible to increase an exhaust volume without increasing exhaust facilities.

Furthermore, according to the present invention, it is possible to increase an exhaust volume without utilizing exhaust components that require a power source or replacement, such as fans.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a longitudinal sectional view schematically illustrating an exemplary embodiment of a liquid treating chamber of FIG. 1.

FIG. 3 is an enlarged longitudinal sectional view of an exhaust amplifier illustrated in FIG. 2.

FIG. 4 is a longitudinal cross-sectional view illustrating an acceleration gas flow in the exhaust amplifier illustrated in FIG. 3.

FIG. 5 is a longitudinal cross-sectional view of the exhaust amplifier illustrated in FIG. 3 with no acceleration gas supplied.

FIG. 6 is a longitudinal cross-sectional view of the exhaust amplifier illustrated in FIG. 3 with acceleration gas supplied at a first flow speed.

FIG. 7 is a longitudinal cross-sectional view of the exhaust amplifier illustrated in FIG. 3 with acceleration gas supplied at a second flow speed.

FIG. 8 is an enlarged longitudinal cross-sectional view of an exhaust amplifier of a substrate processing apparatus according to another exemplary embodiment of the present invention.

FIG. 9 is a longitudinal cross-sectional view illustrating the flow of acceleration gas to the exhaust amplifier illustrated in FIG. 8.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

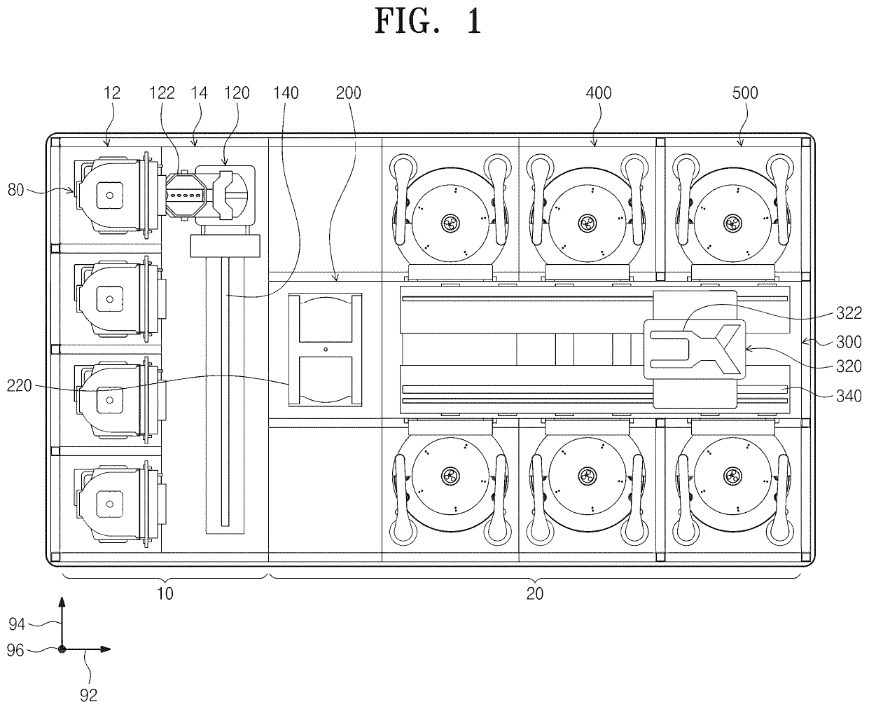

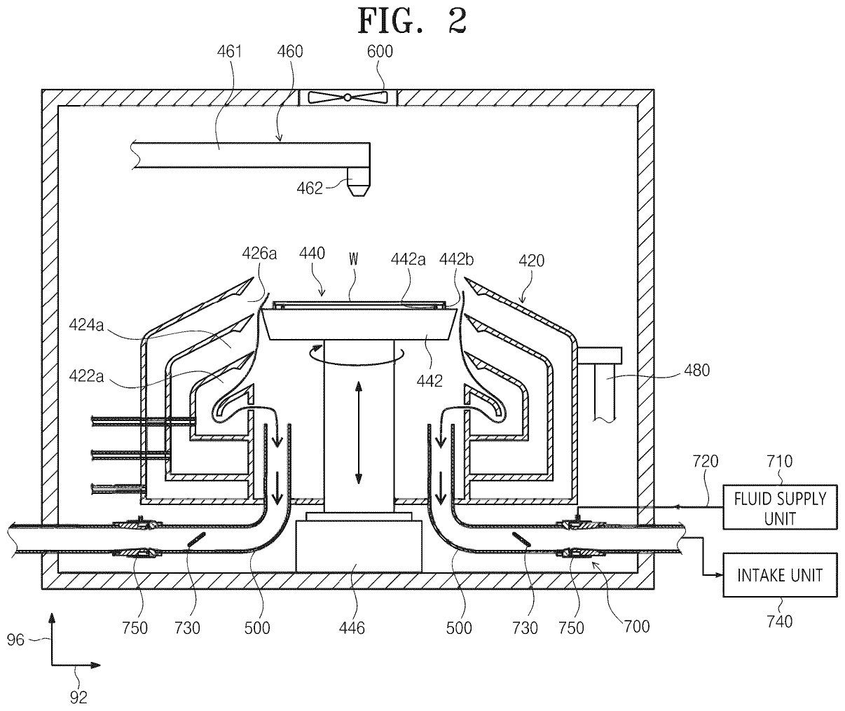

FIG. 1 is a top plan view schematically illustrating a substrate processing apparatus according to an exemplary embodiment of the present invention. FIG. 2 is a diagram schematically illustrating an exemplary embodiment of the liquid treating chamber of FIG. 1. The present exemplary embodiment describes, as an example, a cleaning process in which a substrate is chemically treated and rinsed. However, the present exemplary embodiment is not limited to a cleaning process, but is applicable to a process of processing a substrate with a treatment liquid, such as an etching process, an ashing process, and a development process.

FIG. 1 is a top plan view schematically illustrating a substrate processing apparatus according to an exemplary embodiment of the present invention. Referring to FIG. 1, the substrate processing apparatus includes an index module 1000 and a processing module 20. According to the exemplary embodiment, the index module 10 and the processing module 20 are disposed in one direction. Hereinafter, the direction in which the index module 10 and the processing module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the processing module 20, and accommodates the substrate W completely processed in the processing module 20 in the container 80. A longitudinal direction of the index module 10 is provided in the second direction 94. The index module 10 includes a load port 12 and an index frame 14. Based on the index frame 14, the load port 12 is located at a side opposite to the processing module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transport means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. The plurality of hands 122 is provided while being spaced apart from each other in the vertical direction, and is capable of independently moving forward and backward.

The processing module 20 includes a buffer unit 200, a transfer chamber 300, and a liquid treating chamber 400. The buffer unit 200 provides a space in which the substrate W loaded into the processing module 20 and the substrate W unloaded from the processing module 20 stay temporarily. The liquid treating chamber 400 performs a liquid treatment process of treating the substrate W with a liquid by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. The liquid treating chamber 400 may be disposed at a side portion of the transfer chamber 300. The liquid treating chamber 400 and the transfer chamber 300 may be disposed in the second direction 94. The buffer unit 200 may be located at one end of the transfer chamber 300.

According to one example, the liquid treating chambers 400 may be disposed on opposite sides of the transfer chamber 300, and the liquid treating chambers 400 may be provided in an arrangement of A×B (A and B are each 1 or a natural number greater than 1) along the first direction 2 and the third direction 96 on one side of the transfer chamber 300.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forward and backward, rotatable about the third direction 96, and movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

FIG. 2 is a diagram schematically illustrating an exemplary embodiment of the liquid treating chamber of FIG. 1. Referring to FIG. 2, a liquid treating chamber 400 has a housing 410, a cup 420, a support unit 440, a liquid discharge unit 460, a lifting unit 480, and a fan unit 600.

The housing 410 is provided in a generally rectangular parallelepiped shape. A processing space is formed on the inner side of the housing 410, and a cup 420, a support unit 440, and a liquid discharge unit 460 are arranged in the processing space.

The cup 420 has a processing space with an open top, and the substrate W is liquid-treated in the processing space. The support unit 440 supports the substrate W within the processing space. The liquid discharge unit 460 supplies liquid to the substrate W supported by the support unit 440. The liquid may be provided in a plurality of types, and may be sequentially supplied onto the substrate W. The lifting unit 480 adjusts the relative height between the cup 420 and the support unit 440.

According to the example, the cup 420 includes a plurality of collection containers 422, 424, and 426. Each of the collection containers 422, 424, and 426 has a collection space of collecting the liquid used for the treatment of the substrate. Each of the collection containers 422, 424, and 426 is provided in a ring shape that surrounds the support unit 440. When the liquid treatment process is in progress, the treatment liquid scattered by the rotation of the substrate W is introduced into the collection space through inlets 422a, 424a, and 426a of the respective collection containers 422, 424, and 426.

According to the example, the cup 420 includes a first collection container 422, a second collection container 424, and a third collection container 426. The first collection container 422 is disposed to surround the support unit 440, the second container 424 is disposed to surround the first collection container 422, and the third container 426 is disposed to surround the second collection container 424. A second inlet 424a, which introduces the liquid into the second collection container 424, may be located above a first inlet 422a, which introduces the liquid into the first collection container 422, and a third inlet 426a, which introduces the liquid into the third collection container 426, may be located above the second inlet 424a.

The support unit 440 has a support plate 442 and a drive shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance.

A chuck pin 442b is provided to an edge of the support plate 442. The chuck pin 442b is provided to protrude upwardly from the support plate 442, and supports the lateral portion of the substrate W so that the substrate W is not separated from the support unit 440 when the substrate W is rotated. The driving shaft 444 is driven by a driver 446, is connected to the center of the bottom surface of the substrate W, and rotates the support plate 442 with respect to the central axis thereof.

The lifting unit 480 moves the cup 420 in the vertical direction. By the vertical movement of the cup 420, a relative height between the cup 420 and the substrate W is changed. This changes the collection containers 422, 424, and 426 for collecting the treatment liquid depending on the type of liquid supplied to the substrate W, so that the liquids may be collected separately. As described above, the cup 420 is fixedly installed, and the lifting unit 480 is capable of moving the support unit 440 in an upward and downward direction.

The liquid supply unit 460 supplies the treatment liquid onto the substrate W. The liquid discharge unit 460 includes an arm 461 and a nozzle 462 that is fixedly coupled to an end of the arm 461 and discharges a liquid onto the substrate W.

In one example, a plurality of liquid discharge units 460 are provided, and each of the plurality of liquid discharge units 460 may supply a different type of treatment liquid to the substrate W. The treatment liquid may be any one selected from chemicals, pure water, and organic solvents. For example, the first treatment liquid chemical may include diluted sulfuric acid (H₂SO₄), phosphoric acid (P₂O₅), hydrofluoric acid (HF), and ammonium hydroxide (NH₄OH). Additionally, the second treatment liquid may be pure water or an organic solvent. The organic solvent may be isopropyl alcohol (IPA).

The fan unit 600 supplies air to the interior of the liquid treating chamber 400. The fan unit 600 may be installed in an upper region of the liquid treating chamber 400 to suck air, thereby supplying air to the cup 420 side. The fan unit 600 may be configured in the form of a fan that sucks air. In addition, the fan unit 600 may further include a filter for filtering foreign matters in the air. However, the present invention does not limit the fan unit 600 to the above examples, and it is of course understood that the fan unit 600 may be transformed into any form capable of supplying air, such as a pneumatic pump, a ring blower, an air compressor, an air compression tank, and the like, that supplies purified air.

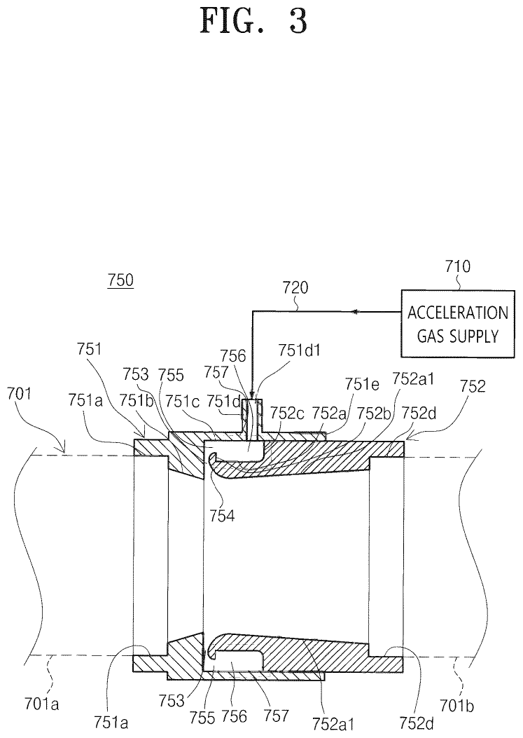

FIG. 3 is an enlarged longitudinal sectional view of a surrounding region of an exhaust amplifier illustrated in FIG. 2.

Referring further to FIG. 3, the exhaust unit 700 includes an exhaust pipe 701, an acceleration gas supply 710, an acceleration gas supply line 720, an intake unit 740, and an exhaust amplifier 750.

The exhaust pipe 701 is connected to the processing space of the housing 410. Further, the exhaust pipe 701 may be configured to communicate with the cup 420 at one end to suck air inside the cup 420. In one example, the exhaust pipe 701 may be formed in a tubular shape so that an end thereof protrudes upwardly through the bottom surface of the cup 420. Additionally, the exhaust pipe 701 may be formed such that a portion of the body is curved to extend along the lower space of the cup 420 and communicate with the outside of the liquid treating chamber 400. Additionally, the exhaust pipe 701 may communicate with the housing 410 to be connected with the cup 420. However, the present invention is not intended to limit the connection relationship of the exhaust pipe 701 to the cup 420 and the housing 410 to the manner described above. As such, the exhaust pipe 701 is connected to the intake unit 740 to intake exhaust gas inside the processing space. In the present exemplary embodiment, the exhaust gases are exemplified to include fumes and by-products. Further, in the present exemplary embodiment, the exhaust pipe 701 may include a first exhaust pipe 701a inserted into the first insertion region 751a and a second exhaust pipe 701b inserted into the second insertion region 752d. Here, the exhaust pipe 701 may be formed by further including a damper 730. Accordingly, the liquid treating chamber 400 may further include the damper 730. The damper 730 is installed in the passage of the exhaust pipe 701 to regulate the exhaust volume of the exhaust gas. For example, the damper 730 may be configured in the form of installing a plate between the exhaust pipe 701 and adjusting the angle of the plate with a motor (not illustrated) coupled to the plate. However, the present invention is not intended to limit the damper 730 in the manner described above, and the damper 730 may be modified and implemented as any of a variety of flow regulating devices that are capable of regulating the amount of air exhausted by installing a plate on the inner side of the exhaust pipe 701.

The acceleration gas supply 710 is a device that supplies an acceleration gas, such as air or nitrogen gas. Such the acceleration gas supply 710 may be implemented in various configurations to supply acceleration gas, such as a pneumatic pump, a ring blower, an air compressor, and an air compression tank. Further, the acceleration gas supply 710 may selectively adjust the pressure and amount of acceleration gas supplied. Furthermore, the acceleration gas supply 710 may be operated to supply acceleration gas at all times, and an acceleration gas opening and closing valve (not illustrated) may be further installed to ensure that acceleration gas is supplied only when the substrate W is processed. In the present exemplary embodiment, the acceleration gas may be formed from air or nitrogen gas. However, the present invention does not limit the type of acceleration gas to the above-mentioned air or nitrogen gas, and it is of course that the acceleration gas may be transformed and formed of various types of gas depending on the type of fume or by-product mixed in the exhaust gas.

The acceleration gas supply line 720 connects between the exhaust amplifier 750 and the acceleration gas supply 710, and delivers the acceleration gas discharged from the acceleration gas supply 710 to the exhaust amplifier 750. In this case, the acceleration gas supply line 720 may be constructed of a rigid material or a flexible pipe, or an optional combination thereof.

The intake unit 740 may be connected to the end of exhaust pipe 701 or to an exhaust line (not illustrated) connected with the exhaust pipe 701 to suck in fumes and byproducts introduced into the exhaust pipe 701. The an intake unit 740 may be configured as any form capable of sucking air, such as a vacuum pump, an in-line pump, or a ring blower. Here, the intake unit 740 may be connected to the exhaust pipe 701 provided in each of the plurality of liquid treating chambers to intake air. Accordingly, the intake unit 740 sucks air of each of the exhaust pipes 701 at a preset intake amount, and when the preset intake amount is exceeded, the intake unit 740 may be adjusted to not exceed the preset intake amount by adjusting the exhaust volume of the damper 730 in conjunction with the damper 730. In this case, the exhaust amplifier 750, which will be described later, serves to increase the exhaust volume by increasing the exhaust speed even when the exhaust volume is regulated by the damper 730 and the exhaust volume is reduced, and will be described in detail later.

The exhaust amplifier 750 is connected in communication with the exhaust pipe 701. In this case, the exhaust pipe 701 may be divided based on the point connected with the exhaust amplifier 750, and the divided exhaust pipe 701 may be coupled to communicate with each of the opposite ends of the exhaust amplifier 750. However, in the present invention, the coupling location of the exhaust amplifier 750 and the exhaust pipe 701 is not limited to the location illustrated in the above example and drawings, and it is a matter of course that the exhaust amplifier 750 may also be installed in an exhaust line (not illustrated) formed on an exterior side of the housing 410 to discharge exhaust gas. Additionally, the exhaust amplifier 750 may be formed in a tubular shape. In one example, the exhaust amplifier 750 may be formed in a cylindrical cylinder shape in communication with the exhaust pipe 701. Additionally, the exhaust amplifier 750 is connected to the acceleration gas supply line 720 to receive acceleration gas supplied from the acceleration gas supply 710. In this case, the exhaust amplifier 750 may amplify the exhaust flow speed by discharging the acceleration gas toward the direction in which the exhaust gas is discharged. In this case, the exhaust amplifier 750 may further amplify the exhaust flow speed by ensuring that the acceleration gas is supplied along the entire face of the inner circumference through which the acceleration gas is introduced when discharging the acceleration gas. In this way, the exhaust amplifier 750 amplifies the exhaust volume of fumes and by-products generated during the processing of the substrate W by supplying the acceleration gas supplied from the acceleration gas supply 710 to the exhaust pipe 701 side, so that the fumes and by-products may be effectively removed without utilizing a separate fan (not illustrated) or the like. Therefore, since the exhaust amplifier 750 does not utilize a fan (not illustrated) as in the related art, it is not necessary to reserve space for installing a fan (not illustrated) and a power source (not illustrated), and thus it is not necessary to proceed with replacement and inspection for maintenance. In addition, the exhaust amplifier 750 amplifies the exhaust volume of fumes and by-products, which may allow for a shorter drying time of the substrate W than in the related art.

As one example of the exhaust amplifier 750, the exhaust amplifier 750 may include a first body 751 and a second body 752.

The first body 751 includes a first insertion region 751a, a protruding region 751b, a first region 751c, an inlet pipe 751d, and an extended region 751e.

The first insertion region 751a is schematically formed in a ring shape. In the inner surface of the first insertion region 751a, the first exhaust pipe 701a is inserted.

The protruding region 751b is schematically formed in a ring shape and is formed by extending from the first insertion region 751a in the direction of the discharge of the exhaust gas. In this case, the inner diameter of the protruding region 751b is formed by protruding toward the center of the exhaust amplifier 750 to have a diameter smaller than the inner diameter of the first insertion region 751a. In this case, the inner diameter of the protruding region 751b is provided so that the area of the inner passage narrows in the direction of the discharge of the exhaust gas. This protruding region 751b increases the flow speed near the center of the passage of the exhaust amplifier 750 over the flow speed of exhaust gas flowing on the inner circumferential side of the passage of the exhaust amplifier 750, thereby amplifying the exhaust volume near the center of the passage. Further, the protruding region 751b is formed in a region where the acceleration gas does not flow. Furthermore, the protruding region 751b is formed to intercept the acceleration gas discharged from the buffer-side outlet passage 755 described later. In this case, a gap space 753 is formed between the protruding region 751b and the buffer-side outlet passage 755, and the acceleration gas is discharged through the gap space 753. The protruding region 751b serves to induce the flow of acceleration gas to a curved surface 754 described later by having a portion of the protruding region obstruct the acceleration gas discharged to the buffer-side outlet passage 755.

The first region 751c is schematically formed in a ring shape. The first region 751c is formed by extending from the protruding region 751b in the direction in which the exhaust gas is discharged. The first region 751c has an inner diameter larger than the inner diameter of the protruding region 751b. As such, the first region 751c provides a region in which the inlet pipe 751d is formed, and serves to seal so that the acceleration gas is not discharged.

The inlet pipe 751d communicated with the first region 751c and protrudes to the outer circumferential side of the first region 751c. In the inlet pipe 751d, an inlet passage 751d1 is formed in communication with the passage of the exhaust amplifier 750, and acceleration gas is introduced into the inlet passage 751d1. The inlet pipe 751d is connected with the acceleration gas supply line 720 to receive acceleration gas, and supplies the received acceleration gas to the buffer space 756 of the exhaust amplifier 750.

The expansion region 751e is schematically formed in a ring shape. Further, the expansion region 751e is formed by extending in the direction in which exhaust gas is discharged from the first region 751c. The expansion region 751e surrounds the outer circumference of the second body 752 to increase the binding force and sealing force with the second body 752 when the first body 751 is coupled with the second body 752. In this case, the inner circumference of the expansion region 751e may be coupled with the second body 752 by fitting or bonding.

The second body 752 includes a second region 752a, a third region 752b, a fourth region 752c, and a second insertion region 752d.

The second region 752a is schematically formed in a ring shape. The outer diameter of the second region 752a is formed to be less than the outer diameter of the first region 751c. Further, the second region 752a is spaced apart from the first region 751c. The second region 752a is disposed at a position opposite to the inlet pipe 751d. Thus, the buffer space 756 is formed between the second region 752a of the second body 752 and the first region 751c of the first body 751. In addition, an inclined surface 752a1 is further formed on the inner peripheral surface of the second region 752a so that the inner diameter gradually increases toward the direction from which the exhaust gas is discharged. Accordingly, the center passage of the exhaust amplifier 750 is provided so that the area of the center passage increases toward the direction from which the exhaust gas is discharged.

The third region 752b is schematically formed in a ring shape. The third region 752b is formed by protruding from the second region 752a in the direction in which the first region 751c is disposed. In this case, the outer diameter of the third region 752b is formed to be less than the inner diameter of the first region 751c. Accordingly, the buffer-side outlet passage 755 is formed between the first region 751c and the first region 751c. Additionally, the buffer-side outlet passage 755 is formed in a ring shape. Further, the buffer-side outlet passage 755 is not formed such that the direction in which the acceleration gas is discharged is the same as the direction in which the acceleration gas discharged through the inlet passage 751d1 is discharged. Furthermore, the buffer-side outlet passage 755 is formed to occupy an area less than the area of the buffer space 756, so that the acceleration gas in the buffer space 756 is trapped in the buffer space 756 to a certain pressure. Thus, the acceleration gas in the buffer space 756 is not discharged directly to the buffer-side outlet passage 755, but is circulated in a vortex form throughout the entire ring-shaped section until the pressure within the buffer space 756 increases to a certain pressure, and then is discharged to the entire inner circumference surface of the buffer-side outlet passage 755 when the pressure exceeds the certain pressure.

The fourth region 752c is schematically formed in a ring shape. The fourth region 752c is formed by protruding upwardly from the second region 752a and extending in the direction of exhaust gas flow. Accordingly, the outer diameter of the fourth region 752c is formed larger than the outer diameter of the second region 752a. Furthermore, the fourth region 752c is disposed opposite to the third region 752b. The outer peripheral surface of the fourth region 752c is inserted into the inner peripheral surface of the expansion region 751e. In this case, the fourth region 752c may be coupled to the extended region 751e by fitting or bonding. Furthermore, the inner peripheral surface of the fourth region 752c is formed with the inclined surface 752a1 provided to widen the area of the passage in the direction from which the exhaust gas is discharged. Thus, when the exhaust gas passes through the inner peripheral surface of the fourth region 752c, the exhaust area is increased and the exhaust volume is further amplified by the flow speed of the acceleration gas.

The second insertion region 752d is schematically formed in a ring shape. The second insertion region 752d is formed by extending from the fourth region 752c. In the inner circumference of the second insertion region 752d, the second exhaust pipe 701b is inserted.

As described above, the first body 751 and the second body 752 are coupled to each other in a separate state, which provides for higher machinability and assembling performance than the first body 751 and the second body 752 are fabricated as a single piece. Accordingly, the first body 751 and the second body 752 may be screwed together, joined by gaskets and parallels, bonded or fused, or the like.

Furthermore, the buffer space 756 is formed between the first body 751 and the second body 752. In this case, the buffer space 756 is enclosed and formed by the acceleration gas-side housing 757. Accordingly, the acceleration gas-side housing 757 may be configured in the form of a housing including the first region 751c, the second region 752a, the third region 752b, the fourth region 752c, and the buffer-side exhaust passage 755 as described above.

In this case, the acceleration gas-side housing 757 forms the inlet passage 751d1 and the buffer-side outlet passage 755 with different discharge directions of the acceleration gas with the buffer space 756 interposed therebetween. Accordingly, the acceleration gas-side housing 757 causes the acceleration gas supplied through the inlet passage 751d1 to be discharged into the buffer-side outlet passage 755, but guides the discharge path of the acceleration gas so that the discharge path of the acceleration gas faces the inner surface of the exhaust amplifier 750.

Furthermore, the buffer space 756 formed on the inner side of the acceleration gas-side housing 757 is formed with an area larger than the inlet passage 751D1 and the buffer-side outlet passage 755. Accordingly, the buffer space 756 temporarily traps the acceleration gas discharged from the inlet pipe 751d, but allows the acceleration gas to be discharged from the buffer-side outlet passage 755 when the pressure of the trapped acceleration gas increases above a certain level. In this case, the buffer space 756 is formed in a structure in which the region excluding the buffer-side outlet passage 755 from which the acceleration gas is discharged is obstructed. Accordingly, the acceleration gas discharged from the inlet passage 751d1 is trapped by the buffer space 756 so that its flow is temporarily impeded, thereby increasing the pressure within the buffer space 756, and the acceleration gas whose pressure is increased by the buffer space 756 is discharged with a strong pressure through the buffer-side outlet passage 755. As such, the buffer space 756 strongly injects the acceleration gas toward the exhaust amplifier 750, thereby increasing the exhaust volume of fumes and by-products and effectively removing fumes and by-products.

Further, the buffer space 756 formed by the acceleration gas-side housing 757 is formed in a ring shape. Therefore, the acceleration gas discharged from the buffer space 756 is discharged from the entire inner peripheral surface of the exhaust amplifier 750 to amplify the exhaust volume.

In addition, the exhaust amplifier 750 may be formed to curve the surface of the inner periphery in the direction of the discharge of the exhaust gas from the location where the acceleration gas is discharged, so that the acceleration gas travels along the curved surface. Accordingly, the exhaust amplifier 750 may be formed to further include the curved surface 754.

In the present exemplary embodiment, the curved surface 754 is formed to curve toward the inner surface of the exhaust amplifier 750 along the buffer-side exhaust passage 755 and the gap space 753 to guide the acceleration gas. Accordingly, the curved surface 754 is formed by extending along the outer surface of the third region 752b, which contacts the buffer-side outlet passage 755 and the gap space 753, to the inclined surface 752a1 formed on the inner circumference of the second region 752a. These curved surface 754 is formed to be curved in the direction of the discharge of the exhaust gas from the buffer-side outlet passage 755, which is the location where the exhaust gas is discharged, in the center of the surface of the inner periphery of the exhaust amplifier 750, thereby guiding the acceleration gases along the direction in which the fumes and byproducts are discharged. In this case, the curved surface 754 may create a Coanda effect when guiding the acceleration gas to induce the acceleration gas. The Coanda effect is a phenomenon in which jet fluid injected tangentially to a curved surface flows along the curved surface of an object while being in close contact with the surface. Accordingly, the exhaust gas including fumes and by-products generated during the processing of the substrate W flows faster by the acceleration gas flowing along the curved surface 754 of the exhaust amplifier 750, thereby increasing the exhaust speed of the exhaust gas. Thus, the exhaust gas is amplified by the acceleration gas flowing along the curved surface 754.

On the other hand, the above-described exhaust unit 700 may be optionally further configured with acceleration gas connection elements, such as valves, or pressure reducing members and static pressure regulators and check valves and filters, which are not illustrated, optionally connected to the acceleration gas supply line 720, as required, and a description of the elements that may be so further configured will be omitted so as not to obscure the essence of the present invention.

Additionally, the exhaust unit 700 may be formed in plural, and each of the plurality of exhaust units may discharge exhaust gas having different chemical properties when it is necessary to discharge exhaust gas having different chemical properties of fumes and by-products depending on the processing process. For example, when two exhaust units 700 are configured, one exhaust unit 700 may discharge alkaline fumes and by-products and the other exhaust unit 700 may discharge acidic fumes and by-products.

In the following, the operational effect according to the driving during the exhaust of the substrate processing device as described above will be described.

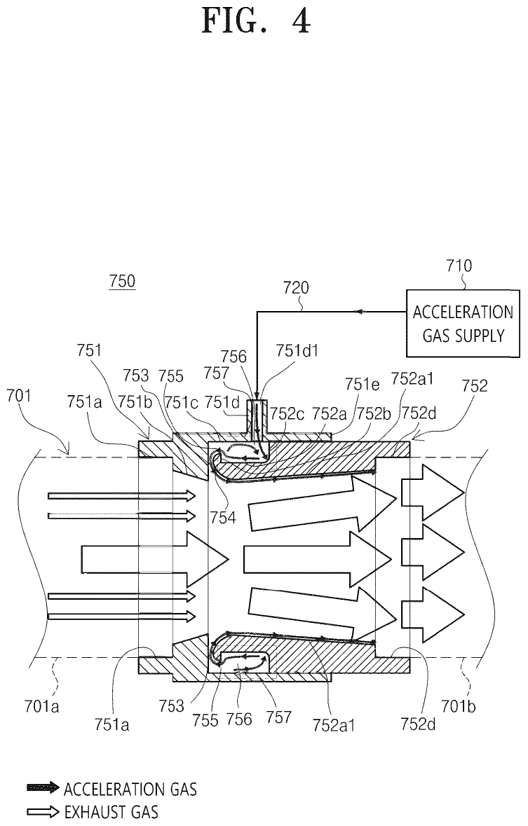

FIG. 4 is a longitudinal cross-sectional view illustrating an acceleration gas flow in the exhaust amplifier illustrated in FIG. 3. Here, in the present invention, the acceleration gas and the exhaust gas illustrated in the drawings are illustrated with arrows in the direction of flow for convenience of understanding, and the size of the arrows is relatively large when the size of the flow speed changes.

A substrate processing method of the present invention will be described with further reference to FIG. 4. First, the transfer robot 320 loads a substrate to the support unit 440 of the liquid treating chamber 400.

Next, in the substrate processing method, while the substrate W supported by the support unit 440 is rotated, the treatment liquid of the liquid discharge unit 460 is supplied to the substrate W through the nozzle 462. In this case, the liquid discharge unit 460 may treat the substrate W by sequentially supplying a first treatment liquid and a second treatment liquid described above through the nozzle 462. At this time, the substrate W is raised by the lifting unit 480 during the treatment with the first treatment liquid and the treatment with the second treatment liquid, so that the by-products generated during the treatment are collected in the inlets 422a, 424a, and 426a of the different collection containers 422, 424, and 426. In this case, the second treatment liquid may be a liquid which is formed from water or an organic solvent and has more fumes produced than the first treatment liquid, which is alkaline or acidic.

In this way, in the process of treating the substrate W, the substrate processing method causes the exhaust unit 700 to discharge exhaust gas including fumes and by-products generated in the liquid treatment of the substrate W to the exhaust pipe 701.

More specifically, the intake unit 740 intakes the exhaust pipe 701, and the exhaust gas is sequentially exhausted through the passage of the first exhaust pipe 701a, the passage of the exhaust amplifier 750, and the passage of the second exhaust pipe 701b.

In this case, the exhaust gas passing through the passage of the first exhaust pipe 701a passes through the inner circumference of the protruding region 751b having a decreasing inner diameter, and the inner diameter of the protruding region 751b is provided such that the area of the passage narrows in the direction from which the exhaust gas is discharged. Accordingly, among the exhaust gas passing through the passage of the protruding region 751b, the exhaust gas passing near the center of the passage have an increased flow speed, and the exhaust volume is amplified.

Next, the exhaust gas that has passed through the passage of the protruding region 751b is accelerated by acceleration gas, in which case the acceleration gas is supplied to the inlet passage 751d1 side of the exhaust amplifier 750 via the acceleration gas supply 710 and the acceleration gas supply line 720.

Then, the acceleration gas discharged from the inlet passage 751d1 side enters the buffer space 756 side. In this case, the acceleration gas introduced into the buffer space 756 is disturbed in its flow through the third region 752B and circulates in the ring-shaped buffer space 756 in the form of a vortex until the pressure in the buffer space 756 increases to a certain pressure or more.

Next, when the pressure within the buffer space 756 increases to the certain pressure or more, the acceleration gas within the buffer space 756 is discharged from the buffer-side outlet passage 755 in a pressurized state. In this case, the acceleration gas is discharged to the entire inner circumference of the exhaust amplifier 750 by the ring-shaped buffer-side exhaust passage 755.

Next, the acceleration gas discharged from the buffer-side outlet passage 755 is obstructed by a portion of the protruding region 751b and flows into the gap space 753 side, and the inflow acceleration gas in the gap space 753 is induced along the curved surface 754 to the inclined surface 752a1 by the Coanda effect.

At this time, the acceleration gas induced along the curved surface 754 by the Coanda effect is further accelerated along the inclined surface 752a1, which widens the diameter of the passage, and the exhaust gas flowing near the inner circumference of the exhaust amplifier 750 is further amplified by increasing the exhaust speed of the exhaust gas.

Thus, the exhaust gas has an increased exhaust speed in all regions of the exhaust amplifier 750, including the region near the center and the region near the outer periphery of the exhaust amplifier 750, resulting in an increase in the entire exhaust volume.

Hereinafter, the adjustment of the supply amount of the acceleration gas in the substrate processing method of the present invention will be described.

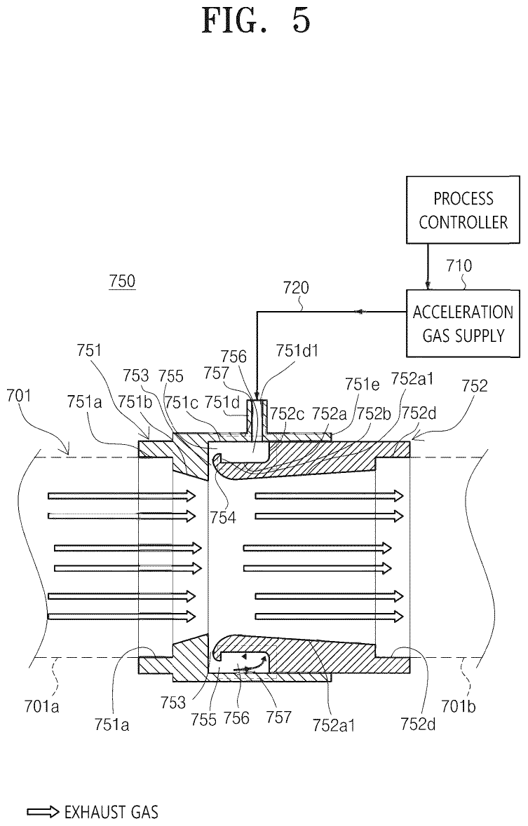

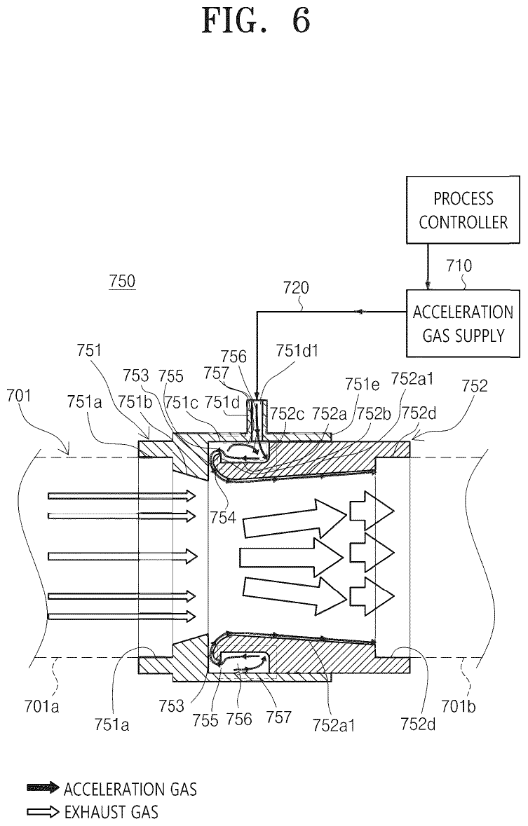

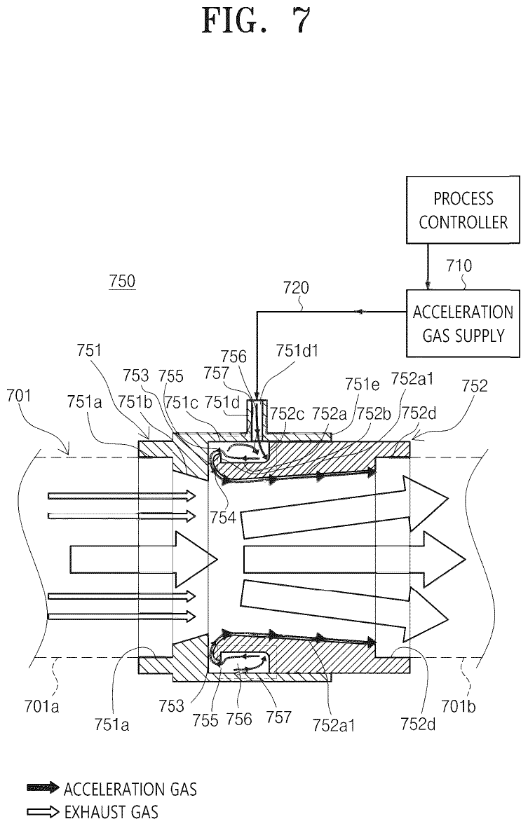

FIG. 5 is a longitudinal cross-sectional view of the exhaust amplifier illustrated in FIG. 3 with no acceleration gas supplied. FIG. 6 is a longitudinal cross-sectional view of the exhaust amplifier illustrated in FIG. 3 with acceleration gas supplied at a first flow speed. FIG. 7 is a longitudinal cross-sectional view of the exhaust amplifier illustrated in FIG. 3 with acceleration gas supplied at a second flow speed.

Referring further to FIGS. 5 to 7, the acceleration gas supply 710 may supply acceleration gas to the passage of the exhaust amplifier 750 by adjusting the flow speed of the acceleration gas based on the untreated state of the process and the type of treatment liquid, thereby efficiently managing the acceleration gas and the power to supply the acceleration gas. In this case, the acceleration gas supply 710 may adjust the amount of acceleration gas supplied by a control drive of the process controller, and the process controller may adjust the amount of acceleration gas supplied differently depending on the state of the process untreated and the state of the treated liquid.

First, the acceleration gas supply 710 may exhaust the atmosphere within the processing space in the state where no acceleration gas is supplied, as illustrated in FIG. 5, when the process is untreated.

Next, as illustrated in FIG. 6, when the substrate W is treated with the first treatment liquid as described above, the acceleration gas supply 710 may discharge the exhaust gas generated by the first treatment liquid by supplying the acceleration gas at a first flow speed to the passage of the exhaust amplifier 750 by adjusting the amount of acceleration gas supplied from a process controller.

Next, as illustrated in FIG. 7, when the substrate W is treated with the second treatment liquid as described above, the acceleration gas supply 710 may supply the acceleration gas at a second flow speed to the passage of the exhaust amplifier 750 by adjusting the supply volume of acceleration gas by the process controller to discharge the exhaust gas generated by the second treatment liquid. In this case, the second treatment liquid may be a liquid which is formed from water or an organic solvent and has more fumes produced than the first treatment liquid, which is alkaline or acidic. Therefore, the acceleration gas supply 710 may amplify the exhaust volume of the exhaust gas depending on the amount of fume generated by supplying the acceleration gas at the second flow speed higher than the first flow speed when supplying the acceleration gas.

As such, the substrate processing apparatus and the substrate processing method of the present invention increase the discharge speed of fumes and by-products by supplying acceleration gas supplied from the acceleration gas supply 710 to the exhaust pipe 701 side, thereby amplifying the exhaust amount of fumes and by-products generated during the processing of the substrate W, so that the fumes and by-products may be effectively removed without using a separate fan (not illustrated) or the like. Thus, since the exhaust amplifier 750 does not utilize a fan (not illustrated) as in the related art, there is no need to prepare a space for installing a fan and a power source, and no need to perform maintenance to replace and check the fan. In addition, the exhaust amplifier 750 amplifies the exhaust volume of fumes and by-products, which may allow for a shorter drying time of the substrate W than in the related art.

Hereinafter, a substrate processing apparatus device according to another exemplary embodiment of the present invention will be described.

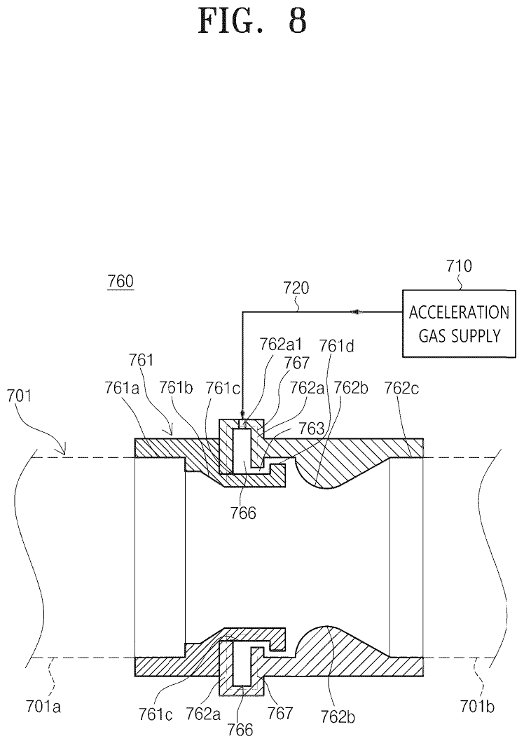

FIG. 8 is an enlarged longitudinal cross-sectional view of an exhaust amplifier of a substrate processing apparatus according to another exemplary embodiment of the present invention.

The substrate processing apparatus according to another exemplary embodiment of the present invention has all of the same components as the substrate processing apparatus described above, except for a second exhaust amplifier 760. Accordingly, the description of the substrate processing apparatus according to another exemplary embodiment of the present invention will focus on the second exhaust amplifier 760. Furthermore, components identical to the aforementioned configuration will be illustrated by using the same reference numerals, and redundant descriptions will be omitted.

The second exhaust amplifier 760 includes a third body 761 and a fourth body 762.

The third body 761 includes a third insertion region 761a, a second protruding region 761b, a second extended region 761c, and a seventh region 761d. The third body 761 is formed in a shape schematically similar to the first body 751.

The third insertion region 761a is schematically formed in a ring shape. The third insertion region 761a provides a region where the first exhaust pipe 701a may be inserted in the inner circumference.

The second protruding region 761b is schematically formed in a ring shape. The second protruding region 761b is formed by extending from the third insertion region 761a in the direction in which the exhaust gas is discharged. The second protruding region 761b is provided so that the area of the passage narrows in the direction from which the exhaust gas is discharged. Therefore, the flow speed near the center is increased when the exhaust gas passes through the second protruding region 761b. The second protruding region 761b may realize the same function as the protruding region 751b described above.

The second extended region 761c is schematically formed in a ring shape. The second extended region 761c is formed by extending from the second protruding region 761b in the direction in which the exhaust gas is discharged. The outer diameter of the second extended region 761c is formed to be less than the outer diameter of the second protruding region 761b. The outer circumference of the second extended region 761c provides a region in which the inner circumference of the fourth body 762 is inserted. In addition, the second extended region 761c may implement a function of any one wall that is combined with an eighth region 762a of the fourth body 762 to form the second acceleration gas-side housing 767.

The seventh region 761b is schematically formed in a ring shape. The seventh region 761d is formed by protruding outwardly from the second extended region 761c to form a diameter larger than the diameter of the second extended region 761c. Further, the seventh region 761d forms a gap space from a second buffer-side outlet passage 763, but serves to block the acceleration gas so that acceleration gas discharged from the second buffer-side outlet passage 763 is not discharged immediately. The seventh region 761d may serve to block the acceleration gas from being discharged immediately, such as the third region 752b of the above-described exemplary embodiment.

The fourth body 762 includes the eighth region 762a, a ninth region 762b, and a fourth insertion region 762c.

The eighth region 762a is schematically formed in a ring shape. Further, the eighth region 762a has a second inlet passage 762a1 communicating from the outer peripheral surface to the inner peripheral surface. The second inlet passage 762a1 is connected to the acceleration gas supply line 720 and is supplied with acceleration gas. Further, the eighth region 762a has a groove formed in a ring shape from the inner passage toward the outer surface. The groove will form a second buffer space 766, which will realize the same role as the buffer space 756 described above. Further, the eighth region 762a forms a ring-shaped second buffer-side outlet passage 763 so that the acceleration gas is discharged in the direction of the discharge of the exhaust gas. The second buffer-side outlet passage 763 implements the same functionality as the buffer-side outlet passage 755 described above, so that a redundant description thereof will be omitted.

The ninth region 762b is schematically formed in a ring shape. The ninth region 762b is formed by extending from the eighth region 762a in the direction from which exhaust gas is discharged. The ninth region 762b has a second curved surface 762b1 formed on the inner circumference. The second curved surface 762b1 is formed in such a way that the area of the passage of the fourth body 762 narrows and then widens again toward the direction in which the exhaust gas is discharged, but the side where the area changes is formed by protruding into a curved surface.

The fourth insertion region 762c is schematically formed in a ring shape. The fourth insertion region 762c is formed by extending from the ninth region 762b in the direction of the discharge of the exhaust gas. In the inner circumference of the fourth insertion region 762c, the second exhaust pipe 701b is inserted. Since the fourth insertion region 762c implements the same function as the second insertion region 752d described above, a redundant description thereof will be omitted.

The second acceleration gas-side housing 767 is formed including the second extended region 761c, the eighth region 762a, and the ninth region 762b, and the second buffer-side outlet passage 763. The second acceleration gas-side housing 767 is formed in a shape in which the second extended region 761c, the eighth region 762a, and the ninth region 762b act as walls to form the second buffer space 766 on the inner side, and the second buffer-side outlet passage 763 through which acceleration gas is discharged in some regions. Here, the second acceleration gas-side housing 767 implements the same function as the acceleration gas-side housing 757 described above.

The third body 761 and the fourth body 762 may be screwed to each other, joined by gaskets and parallels, bonded or fused, or the like.

Meanwhile, hereinafter, a substrate processing method for exhausting exhaust gas by the second exhaust amplifier 760 will be described.

Since the substrate processing method using the second exhaust amplifier 760 proceeds identically to the substrate processing method of the foregoing exemplary embodiment, a redundant description of the identical parts will be omitted, and the differences will be emphasized on the flow of the acceleration gas when exhausting the exhaust gas.

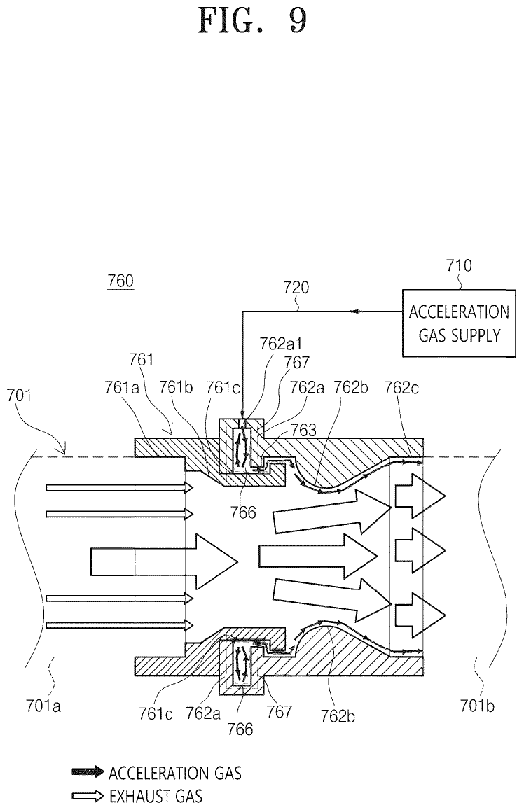

Accordingly, referring further to FIG. 9, FIG. 9 is a longitudinal sectional view illustrating the flow of acceleration gas in the exhaust amplifier illustrated in FIG. 8.

As illustrated in FIG. 9, exhaust gas generated from the processing of the substrate W is introduced to the first exhaust pipe 701a. The exhaust gas introduced into the first exhaust pipe 701a passes through a passage in which the area of the second protruding region 761b is narrowed. In this case, the exhaust gas that passes near the center of the passage increases in flow speed, and the exhaust volume is amplified.

Next, the exhaust gas that has passed through the passage of the second protruding region 761b is accelerated by acceleration gas, in which case the acceleration gas is introduced into the second buffer space 766 through the second inlet passage 762a1 of the eighth region 762a via the acceleration gas supply 710 and the acceleration gas supply line 720.

In this case, the acceleration gas introduced into the second buffer space 766 is trapped by the eighth region 762a and the second extended region 761c while circulating in a form of a vortex until the pressure within the second buffer space 766 increases to a certain pressure or more.

Next, when the pressure in the second buffer space 766 increases to the certain pressure or more, the acceleration gas in the second buffer space 766 is discharged to the second buffer-side outlet passage 763 in a pressurized state. In this case, the acceleration gas is discharged by the ring-shaped second buffer-side outlet passage 763 to the entire inner circumference of the second exhaust amplifier 760.

Next, the acceleration gas discharged from the second buffer-side outlet passage 763 is discharged to the second curved surface 762b1 and flows through the second curved surface 762b1 by the Coanda effect.

In this case, the acceleration gas induced along the second curved surface 762b1 by the Coanda effect is further accelerated as it passes from a section where the diameter of the passes decreases to a section where the diameter of the passage increases, and the exhaust speed of the exhaust gas flowing near the inner circumference of the second exhaust amplifier 760 is further increased to further amplify the exhaust volume.

Thus, the exhaust speed of the exhaust gas is increased in all regions, including the region near the center and the region near the outer periphery of the second exhaust amplifier 760, resulting in an increased overall exhaust volume.

As such, the second exhaust amplifier 760 may also be configured to form the second buffer-side outlet passage 763, the second buffer space 766, and the second acceleration gas-side housing 767 in a different direction from the exhaust amplifier 750 described above. Furthermore, although the exhaust amplifiers 750 and 760 are illustrated as two bodies joined to form the buffer spaces 756 and 766 and the acceleration gas-side housings 757 and 767, the exhaust amplifiers 750 and 760 may be otherwise formed as a single part, or each of the buffer spaces 756 and 766 and acceleration gas-side housings 757 and 767 may be formed as a separate part.

Furthermore, the aforementioned exhaust amplifiers 750 and 760 may be implemented in various variations configured to allow acceleration gas to flow through the inner circumference. It should be appreciated, of course, that the second exhaust amplifier 760 may be applied and configured in various forms, for example, in a form that allows the acceleration gas to flow along the second curved portion 762b1 as is, in the state where a single outlet is formed, without forming the second buffer space 766.

On the other hand, although the substrate processing apparatus and the substrate processing method are exemplified as exhausting fumes and by-products generated during liquid treatment, the substrate processing apparatus and the substrate processing method may exhaust gas generated during other processes. For example, the substrate processing apparatus and the substrate processing method of the present invention may be applied to manufacturing facilities that discharge exhaust gas, such as etching process facilities, diffusion process facilities, and deposition process facilities, and may also be applied where exhaust is required, such as photo resist application process facilities, development process facilities, and heat treatment process facilities.

In other words, although the present invention has been described above with reference to specific matters such as specific components and the like, and with reference to limited exemplary embodiments and drawings, these are provided for a more general understanding of the invention, the invention is not limited to the above exemplary embodiments, and various modifications and variations may be made from these descriptions by those skilled in the art to which the invention belongs.

Therefore, the spirit of the present invention should not be limited to the described exemplary embodiments, and it will be the that not only the claims to be described later, but also all modifications equivalent to the claims belong to the scope of the present invention.

1. An apparatus for processing a substrate, the apparatus comprising:
a processing chamber having a processing space for processing a substrate;
a support unit for supporting the substrate in the processing space;
a liquid supply unit for supplying a liquid to a substrate supported by the support unit; and
an exhaust unit for exhausting the processing space,
wherein the exhaust unit includes:
an exhaust pipe connected to the processing space; and
an exhaust amplifier installed in the exhaust pipe and for supplying acceleration gas to a passage of the exhaust pipe to amplify an exhaust flow rate of exhaust gas flowing in the exhaust pipe.

2. The apparatus of claim 1, wherein the exhaust amplifier includes:
an acceleration gas-side housing having an inlet passage through which the acceleration gas is introduced and a buffer-side outlet passage through which the acceleration gas is discharged; and
a gas supply line connected to the inlet passage to supply the acceleration gas to the inlet passage, and
the acceleration gas-side housing discharges the acceleration gas discharged from the buffer-side outlet passage into a passage of the exhaust pipe.

3. The apparatus of claim 2, wherein the acceleration gas-side housing is disposed so that a direction of discharging the acceleration gas from the inlet passage and a direction of discharging the acceleration gas from the buffer-side outlet passage are not identical to each other.

4. The apparatus of claim 2, wherein the acceleration gas-side housing has a buffer space which communicates with the inlet passage and the buffer-side outlet passage and is formed in an area larger than the inlet passage and the buffer-side outlet passage.

5. The apparatus of claim 4, wherein the buffer space is provided in a ring shape.

6. The apparatus of claim 4, wherein the buffer-side outlet passage is provided in a ring shape.

7. The apparatus of claim 2, wherein the acceleration gas discharged from the buffer-side outlet passage is provided to be discharged in a downstream direction in which the exhaust gas flows.

8. The apparatus of claim 2, wherein the acceleration gas discharged from the buffer-side outlet passage is discharged along a face forming the passage of the exhaust pipe.

9. The apparatus of claim 2, wherein the exhaust amplifier has a curved surface in which a face on which the acceleration gas flows is formed to be curved.

10. The apparatus of claim 9, wherein the acceleration gas discharged from the buffer-side outlet passage is discharged to the curved surface.

11. The apparatus of claim 9, wherein an inner diameter of the curved surface is provided to decrease and then increase in a downstream direction in which the exhaust gas flows.

12. The apparatus of claim 2, wherein the exhaust pipe includes a first exhaust pipe connected to the treating chamber, and a second exhaust pipe, and
the acceleration gas-side housing includes:
a first body connected with the first exhaust pipe; and
a second body connected with the second exhaust pipe, and
the second body and the first body are coupled to each other, and
a buffer space is provided between the first body and the second body.

13. The apparatus of claim 12, wherein the second body is provided so that an area of the passage increases in a direction toward the second exhaust pipe.

14. The apparatus of claim 12, wherein the first body includes:
an insertion region coupled with the first exhaust pipe; and
a protruding region extending from the insertion region in a direction in which the exhaust gas flows, and
the protruding region is provided so that an inner diameter of the passage decreases in the direction in which the exhaust gas flows.

15. The apparatus of claim 14, wherein the first body further includes an extended region extended from the protruding region in a direction in which the exhaust gas flows, and
the second body is engaged with an inner diameter or an outer diameter of the extended region, and
the buffer space is provided between the first body and the second body.

16. The apparatus of claim 1, further comprising:
a damper installed in the exhaust pipe and for adjusting an area of exhaust on a passage through which the exhaust flows.

17.-19. (canceled)

20. An apparatus for processing a substrate, the apparatus comprising:
a processing chamber having a processing space for processing a substrate;
a support unit for supporting the substrate in the processing space;
a liquid supply unit for supplying a liquid to a substrate supported by the support unit; and
an exhaust unit for exhausting the processing space,
wherein the exhaust unit includes:
an exhaust pipe connected to the processing space and exhausting the processing space; and
an exhaust amplifier installed in the exhaust pipe and amplifying an exhaust pressure; and
the exhaust amplifier includes:
an acceleration gas-side housing having an inlet passage through which the acceleration gas is introduced and a buffer-side outlet passage through which the acceleration gas is discharged, and a buffer space which communicates with the inlet passage and the buffer-side outlet passage, is formed in an area larger than the inlet passage and the buffer-side outlet passage, and is provided in a ring shape; and
a gas supply line connected to the inlet passage and for supplying the acceleration gas to the inlet passage, and
the acceleration gas-side housing is disposed so that a direction of discharging the acceleration gas from the inlet passage and a direction of discharging the acceleration gas from the buffer-side outlet passage are not identical to each other, and the acceleration gas discharged from the buffer-side outlet passage is discharged along a face forming a passage of the exhaust pipe.
